(19) United States
(12) Patent Application Publication
(10) Pub. No.: US 2015/0263022 A1
(43) Pub. Date: Sep. 17, 2015

(54) SEMICONDUCTOR MEMORY DEVICE AND MANUFACTURING METHOD THEREOF

(71) Applicant: KABUSHIKI KAISHA TOSHIBA, Minato-ku (JP)

(72) Inventors: Yukinori KOYAMA, Yokkaichi-shi (JP); Toshitaka Miyata, Kawasaki-shi (JP)

(73) Assignee: KABUSHIKI KAISHA TOSHIBA, Minato-ku (JP)

(21) Appl. No.: 14/313,276

(22) Filed: Jun. 24, 2014

Related U.S. Application Data
(60) Provisional application No. 61/951,983, filed on Mar. 12, 2014.

(51) Int. Cl. H01L 27/115; H01L 29/66; H01L 21/265; H01L 29/51; H01L 23/528; H01L 21/768; H01L 29/788; H01L 29/78

(52) U.S. Cl. CPC H01L 27/11546; H01L 29/788; H01L 29/66825; H01L 27/11526; H01L 29/7831; H01L 29/513; H01L 23/528; H01L 21/76897; H01L 21/265

(57) ABSTRACT

The peripheral transistor includes at least a first peripheral transistor and a second peripheral transistor. The first peripheral transistor and the second peripheral transistor each comprise: a first gate electrode formed on a gate insulating film; an inter-gate insulating film formed on a surface of the first gate electrode; a through-hole formed in the inter-gate insulating film; a connecting layer formed in the through-hole; and a second gate electrode formed on a surface of the inter-gate insulating film and connected to the first gate electrode via the connecting layer.

The first gate electrode of the first peripheral transistor is configured by only a semiconductor layer of a first conductivity type. The first gate electrode of the second peripheral transistor comprises a first semiconductor layer of the first conductivity type and a second semiconductor layer of a second conductivity type aligned with the first semiconductor layer along a gate length direction.

### CROSS REFERENCE TO RELATED APPLICATIONS

This application is based on and claims the benefit of priority from prior U.S. provisional Patent Application No. 61/951,983, filed on Mar. 12, 2014, the entire contents of which are incorporated herein by reference.

### FIELD

Embodiments described below relate to a semiconductor memory device and a manufacturing method thereof.

### BACKGROUND

A semiconductor memory device, for example, a NAND type flash memory, includes, on an identical semiconductor substrate, a memory transistor configuring a memory cell array, and a peripheral transistor configuring a peripheral circuit for controlling the memory cell array.

In recent years, further speeding up of the semiconductor memory device is required, and improvement in performance of the peripheral transistor is being required also in the peripheral circuit. Moreover, it is also required that such a peripheral transistor is manufactured by a smaller number of manufacturing steps.

### BRIEF DESCRIPTION OF THE DRAWINGS

FIG. 1 is a block diagram showing an example of configuration of a nonvolatile semiconductor memory device according to a first embodiment.

FIG. 2 is an equivalent circuit diagram showing an example of configuration of a memory cell array 111.

FIG. 3 is a cross-sectional view showing an example of cross-sectional structure of a memory cell MC.

FIG. 4 is a cross-sectional view showing an example of cross-sectional structure of select transistors SG1 and SG2.

FIG. 5 is a cross-sectional view showing an example of cross-sectional structure of one NAND cell unit NU in the memory cell array 111.

FIG. 6 is a cross-sectional view showing an example of configuration of a first transistor Tr1 (single work function MOSFET) configuring a peripheral circuit.

FIG. 7 is a cross-sectional view showing an example of configuration of a second transistor Tr2 (dual work function MOSFET) configuring the peripheral circuit.

FIGS. 8 to 10 are step diagrams describing manufacturing steps of the memory cell MC, the first transistor Tr1, and the second transistor Tr2 of the nonvolatile semiconductor memory device of the first embodiment.

FIG. 11 is a cross-sectional view showing an example of configuration of a second transistor Tr2 (dual work function MOSFET) according to a second embodiment.

FIG. 12 is a cross-sectional view showing an example of configuration of a second transistor Tr2 (dual work function MOSFET) according to a third embodiment.

### DETAILED DESCRIPTION

A semiconductor memory device according to an embodiment described below comprises a memory cell array including a memory transistor, and a peripheral circuit including a peripheral transistor. The peripheral transistor includes at least a first peripheral transistor and a second peripheral transistor. The first peripheral transistor and the second peripheral transistor each comprise: a first gate electrode formed on a gate insulating film; an inter-gate insulating film formed on a surface of the first gate electrode; a through-hole formed in the inter-gate insulating film; a connecting layer formed in the through-hole; and a second gate electrode formed on a surface of the inter-gate insulating film and connected to the first gate electrode via the connecting layer.

The first gate electrode of the first peripheral transistor is configured by only a semiconductor layer of a first conductivity type. The first gate electrode of the second peripheral transistor comprises a first semiconductor layer of the first conductivity type and a second semiconductor layer of a second conductivity type aligned with the first semiconductor layer of the first conductivity type along a gate length direction.

Next, a nonvolatile semiconductor memory device according to embodiments will be described based on the drawings.

### First Embodiment

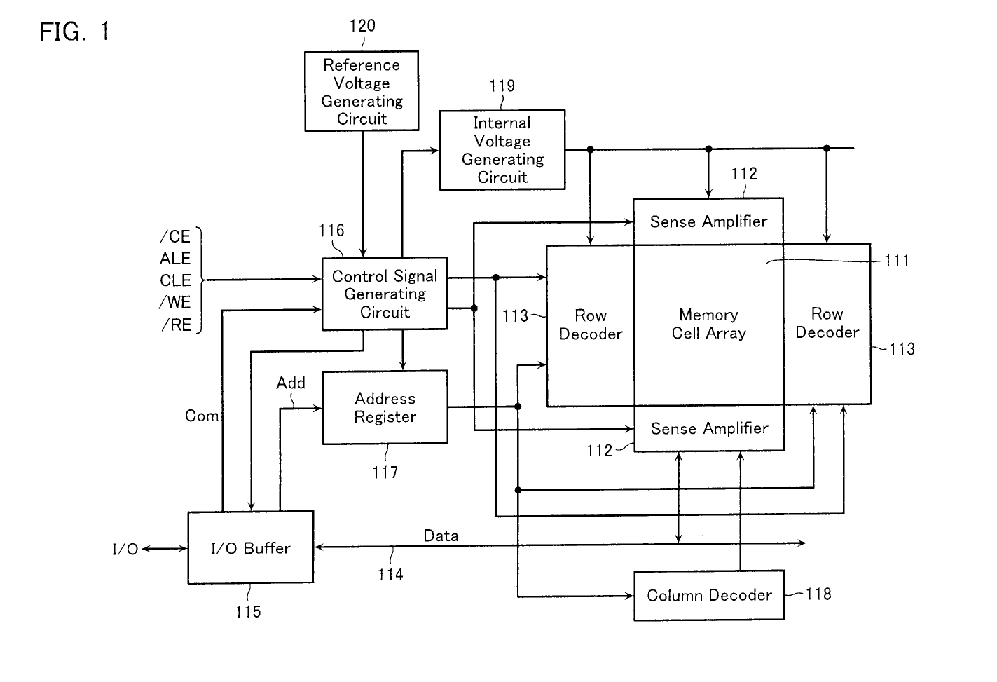

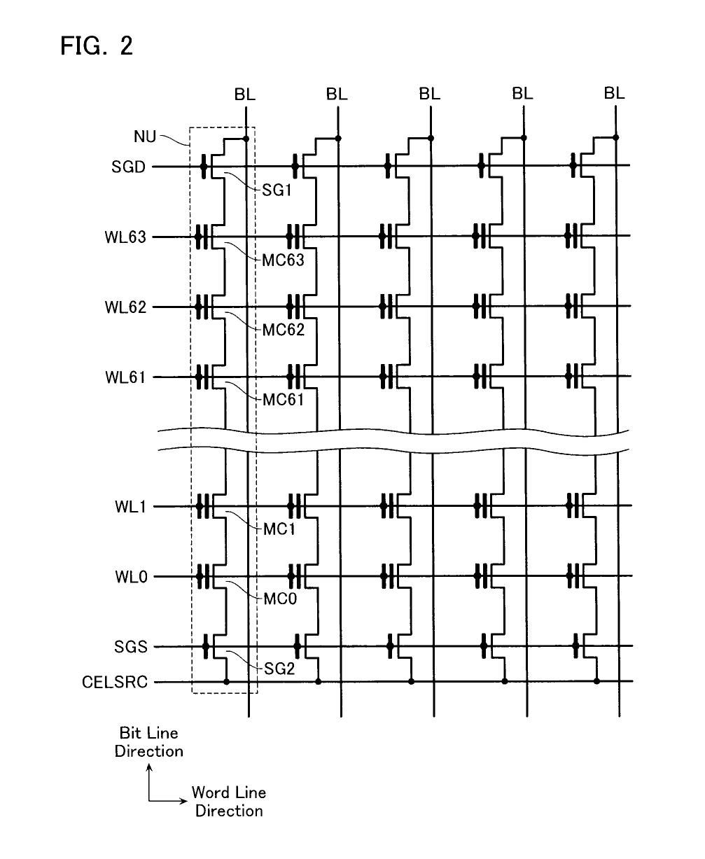

First, an example of configuration of a nonvolatile semiconductor memory device according to a first embodiment will be described with reference to FIGS. 1 and 2. FIG. 1 is a block diagram showing an example of configuration of the nonvolatile semiconductor memory device (NAND type flash memory) according to the first embodiment. FIG. 2 is an equivalent circuit diagram showing an example of configuration of a memory cell array 111. Note that in FIG. 2, a direction in which a word line WL extends is referred to as a word line direction, and a direction in which a bit line BL extends is referred to as a bit line direction.

As shown in FIG. 1, the nonvolatile semiconductor memory device according to the first embodiment includes the memory cell array 111, a sense amplifier 112, a row decoder 113, a data line 114, an I/O buffer 115, a control signal generating circuit 116, an address register 117, a column decoder 118, an internal voltage generating circuit 119, and a reference voltage generating circuit 120.

As shown in FIG. 2, the memory cell array 111 is configured having NAND cell units NU arranged in a matrix therein. Each of the NAND cell units NU includes, for example, 64 series-connected electrically rewritable nonvolatile memory cells MC0 to MC63 (a memory string) and select transistors SG1 and SG2 for respectively connecting the two ends of the memory string to the bit line BL and a common source line CELSRC.

Control gates of the memory cells MC0 to MC63 in the NAND cell unit NU are connected to different word lines WL0 to WL63. Gates of the select transistors SG1 and SG2 are respectively connected to select gate lines SGD and SGS. A group of NAND cell units NU sharing one word line WL configure a block BLK which forms a unit of data erase. Although omitted from the drawings, a plurality of the blocks BLK are arranged in the bit line direction.

Each bit line BL is connected to the sense amplifier 112 shown in FIG. 1. The plurality of memory cells MC commonly connected to one word line WL configure one page or multiple pages.

As shown in FIG. 1, the sense amplifier 112 is disposed in the bit line direction of the memory cell array 111 and as well as being connected to the bit line BL to perform read of a page unit of data. It also serves as a data latch that holds one page of write data. That is, read and write are performed in units of the page. The sense amplifier 112 is provided with a data cache that temporarily holds input/output data and a column select gate circuit that performs column selection (not illustrated).

As shown in FIG. 1, the row decoder 113 is disposed in the word line direction of the memory cell array 111 and selectively drives the word line WL and the select gate lines SGD and SGS according to a row address. This row decoder 113 includes a word line driver and a select gate line driver. In addition, the column decoder 118 that controls the column select gate circuit in the sense amplifier 112 is provided accompanying the sense amplifier 112. The row decoder 113, the column decoder 118, and the sense amplifier 112 configure a read/write circuit for performing data read and write of the memory cell array 111.

Data transfer between an external input/output port I/O and the sense amplifier 112 is performed by the input/output buffer 115 and the data line 114. That is, page data read into the sense amplifier 112 is outputted to the data line 114 to be outputted to the input/output port I/O via the input/output buffer 115. Moreover, write data supplied from the input/output port I/O is loaded into the sense amplifier 112 via the input/output buffer 115.

Address data Add supplied from the input/output port I/O is supplied to the row decoder 113 and the column decoder 118 via the address register 117. Command data Com supplied from the input/output port I/O is decoded to be set in the control signal generating circuit 116.

External control signals, namely a chip enable signal /CE, an address latch enable signal ALE, a command latch enable signal CLE, a write enable signal /WE, and a read enable signal /RE are supplied to the control signal generating circuit 116, respectively. The control signal generating circuit 116 as performs operation control of overall memory operation based on the command Com and the external control signals. In addition, it controls the internal voltage generating circuit 119 to generate various kinds of internal voltages required for data read, write, and erase. Also, the control signal generating circuit 116 is applied with a reference voltage from the reference voltage generating circuit 120. The control signal generating circuit 116 starts writing from a selected memory cell MC on a source line SL side and controls a read operation.

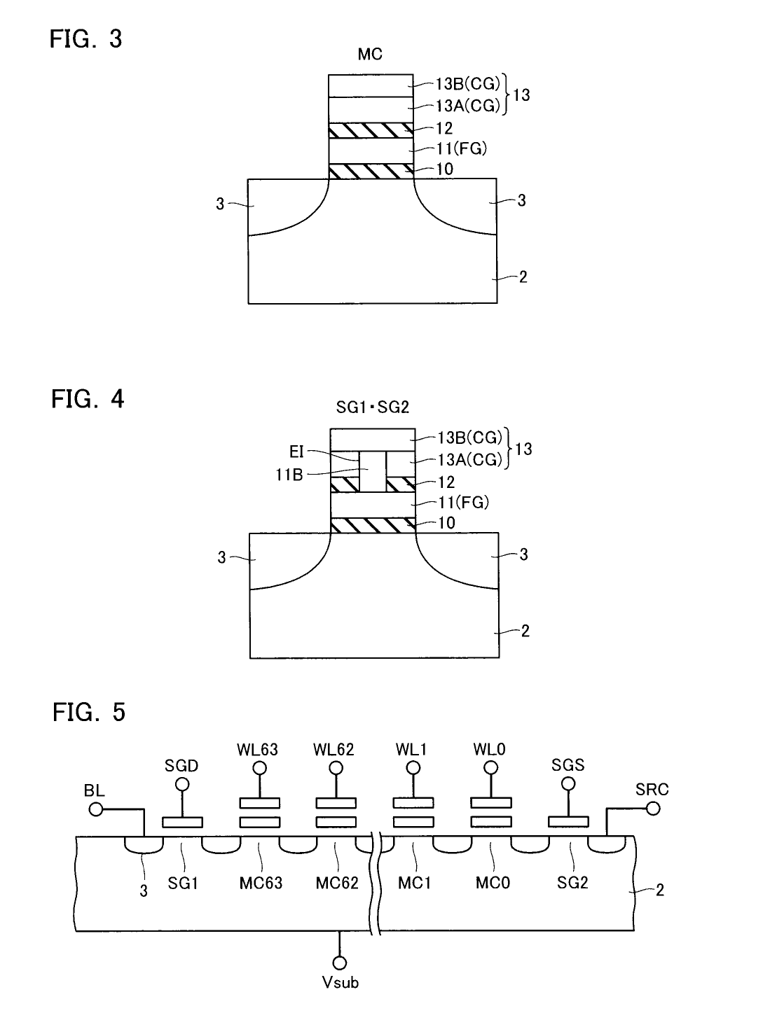

FIGS. 3 and 4 show examples of cross-sectional structures of the memory cell MC (memory transistor) and the select transistors SG1 and SG2.

In the memory cell MC, an n type source and drain diffusion layer 3 is formed in a p type well 2 formed on a semiconductor substrate not illustrated. A region of the p type well 2 sandwiched by two diffusion layers 3 functions as a channel region of a MOSFET configuring the memory cell MC.

Moreover, a floating gate (FG) 11 is formed on the p type well 2 via a gate insulating film 10. The floating gate 11 is configured capable of holding charges therein, and a threshold voltage of the memory cell MC is determined by an amount of that charge. A control gate (CG) 13 is formed on this floating gate 11 via an inter-gate insulating film 12. The control gate 13 has a structure which includes therein a first control gate layer 13A and a second control gate 13B sequentially stacked therein, the first control gate 13A being configured from polysilicon, and the second control gate layer 13B being configured from a metallic film such as tungsten (W) and tungsten nitride (WN), or a stacked structure of a plurality of kinds of metals.

The select transistors SG1 and SG2 comprise the p type well 2 formed on the semiconductor substrate not illustrated and the n type source and drain diffusion layer 3 formed in a surface of this p type well 2. Note that a source and drain using a fringe electric field may be employed instead of the diffusion layer 3.

Formed on the p type well 2 via the gate insulating film 10 are a gate electrode 11, an inter-gate insulating film 12, and a control gate 13 (first control gate layer 13A and second control gate layer 13B). This gate electrode 11 is formed from an identical material to that of the floating gate 11 of the memory cell MC, and may be formed simultaneously to the floating gate 11 of the memory cell MC by an identical deposition step. The inter-gate insulating film 12 also is configured from an identical material to that of the inter-gate insulating film 12 of the memory cell MC, and may be formed simultaneously to the inter-gate insulating film 12 of the memory cell MC by an identical deposition step. Similarly, the control gate 13 also is formed from an identical material to that of the control gate 13 of the memory cell MC, and may be formed simultaneously to the control gate 13 of the memory cell MC by an identical deposition step.

However, in the select transistors SG1 and SG2, a through-hole EI is formed in the inter-gate insulating film 12. Moreover, formed in this through-hole EI is a connecting layer 11B which is configured from a conductive material (for example, polysilicon) and electrically connects the gate electrode 11 and the control gate 13. As a result, the gate electrode 11 and the control gate 13 function as one gate electrode.

FIG. 5 is a cross-sectional view showing an example of cross-sectional structure of one NAND cell unit NU in the memory cell array 111. In this example, one NAND cell unit NU is configured having 64 memory cells MC having the configuration shown in FIG. 3 and the select transistors SG1 and SG2 having the configuration shown in FIG. 4, connected in series. Two adjacent memory cells MC share the source/drain diffusion layer 3.

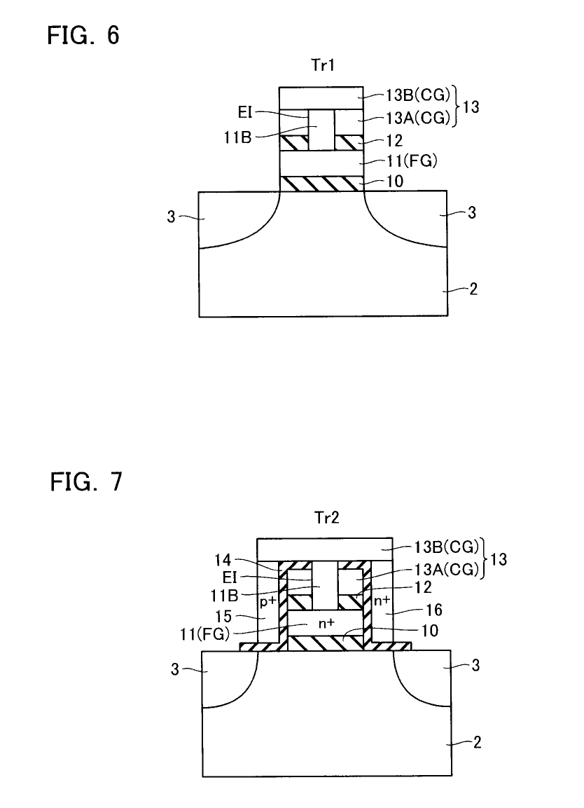

This nonvolatile semiconductor memory device also includes numerous transistors in various kinds of peripheral circuits formed in a periphery of the memory cell array 111. The transistor configuring the peripheral circuit (peripheral transistor) of the nonvolatile semiconductor memory device of the present embodiment is broadly divided into two kinds. One is a first transistor Tr1 of the kind shown in FIG. 6 whose gate electrode has a single work function (single work function MOSFET), and the other is a second transistor Tr2 of the kind shown in FIG. 7 whose gate electrode has two types of work functions (dual work function MOSFET).

Similarly to the select transistors SG1 and SG2, the first transistor Tr1 (single work function MOSFET) of FIG. 6 comprises, for example, a p type well 2, an n type source and drain diffusion layer 3, a gate insulating film 10, a gate electrode 11 (first gate electrode), an inter-gate insulating film 12, and a control gate 13 (second gate electrode: first control gate layer 13A and second control gate layer 13B). This gate electrode 11 is formed from an identical material to that of the floating gate 11 of the memory cell MC, and may be formed simultaneously to the floating gate 11 of the memory cell MC by an identical deposition step. The inter-gate insulating film 12 also is configured from an identical material to that of the inter-gate insulating film 12 of the memory cell MC, and may be formed simultaneously to the inter-gate insulating film 12 of the memory cell MC by an identical deposition step. Similarly, the control gate 13 also is formed from an identical material to that of the control gate 13 of the memory cell MC, and may be formed simultaneously to the control gate 13 of the memory cell MC by an identical deposition step.

A through-hole EI is formed in the inter-gate insulating film 12. Moreover, formed in this through-hole EI is a connecting layer 11B which is configured from a conductive material (for example, polysilicon) and electrically connects the gate electrode 11 and the control gate 13. The connecting layer 11B functions to electrically connect the gate electrode 11 and the control gate 13, whereby the gate electrode 11 and the control gate 13 function as one gate electrode. This gate electrode 11 of the first transistor Tr1 is configured from only an n+ type semiconductor layer, hence the first transistor Tr1 is configured as a single work function MOSFET.

In addition, the second transistor Tr2 (dual work function MOSFET) of FIG. 7 has a dual gate structure in which a p+ type semiconductor layer and an n+ type semiconductor layer are aligned in a gate length direction on the gate insulating film. Therefore, the gate electrode has two types of work functions. A threshold voltage in a portion of the p+ type semiconductor layer is high, and a channel below this p+ type semiconductor layer is an effective channel. Such a dual work function MOSFET has an advantage of being able to suppress a short channel effect while shortening an effective gate length Leff. Such a second transistor Tr2 may be used, for example, as a transistor configuring the I/O buffer 115 of FIG. 1. In addition, the second transistor Tr2 may be used in the likes of a logic circuit unit, an analog circuit unit, and a page buffer circuit not illustrated in FIG. 1.

A structure of the second transistor Tr2 shown as an example in FIG. 7 will be described specifically below. The second transistor Tr2 of FIG. 7 comprises a p type well 2, an n type source and drain diffusion layer 3, a gate insulating film 10 (first gate insulating film), agate electrode 11 (first gate electrode), an inter-gate insulating film 12, and a control gate 13 (second gate electrode: first control gate layer 13A (third semiconductor layer) and second control gate layer 13B (fourth semiconductor layer)). The gate electrode 11 is formed from an identical material to that of the floating gate 11 of the memory cell MC, and may be formed simultaneously to the floating gate 11 of the memory cell MC by an identical deposition step. The inter-gate insulating film 12 also is configured from an identical material to that of the inter-gate insulating film 12 of the memory cell MC, and may be formed simultaneously to the inter-gate insulating film 12 of the memory cell MC by an identical deposition step. Similarly, the control gate 13 also is formed from an identical material to that of the control gate 13 of the memory cell MC, and may be formed simultaneously to the control gate 13 of the memory cell MC by an identical deposition step. In addition, a through-hole EI similar to that of the first transistor Tr1 is formed in the inter-gate insulating film 12. Moreover, formed in this through-hole EI is a connecting layer 11B which is configured from a conductive material (for example, polysilicon) and electrically connects the gate electrode 11 and the control gate 13. As a result, the gate electrode 11 and the control gate 13 function as one gate electrode.

Moreover, a gate electrode 15 (second semiconductor layer) is formed on one side of the gate electrode 11 via a gate insulating film 14 (second gate insulating film). In the case that the gate electrode 11 is configured from an n+ type semiconductor, this gate electrode 15 is formed from a different conductivity type p+ type semiconductor. As will be described later, this gate electrode 15 (p+ type semiconductor layer) is short-circuited with the gate electrode 11 (n+ type semiconductor layer) via the control gate 13 and the connecting layer 11B, and configures a dual gate electrode along with the gate electrode 11. That is, a gate electrode configured from the gate electrode 11 (n+ type), the control gate 13, and the gate electrode (p+ type) has a structure in which a p+ type semiconductor and an n+ type semiconductor are arranged in parallel in a gate length direction on a gate insulating film, hence the second transistor Tr2 functions as a dual gate electrode. In addition, the gate insulating film 14 has its film thickness configured smaller than that of the gate insulating film 10. As a result, the second transistor Tr2 of FIG. 7 configures a multi-gate insulating film/dual work function MOSFET. By making the film thickness of the gate insulating film 14 smaller than the film thickness of the gate insulating film 10, gate control ability by the p+ type gate electrode 15 can be increased and a leak component of the MOSFET can be suppressed.

Note that in the example of FIG. 7, the gate insulating film 14 is formed not only on the p type well 2, but also on side surfaces of the gate electrode 11, the inter-gate insulating film 12, and the first control gate layer 13A and on an upper surface of the first control gate layer 13A. This is a shape resulting from manufacturing steps which will be described later. It is also possible for the gate insulating film 14 formed on the side surface of the gate electrode 11, and so on, to be removed by an additional step.

Moreover, a gate electrode 16 configured from an n+ type semiconductor is formed on a side opposite to the side where the gate electrode 15 of the gate electrode 11 is formed, via a gate insulating film 14 in a similar way. This gate electrode 16 configured from an n+ type semiconductor similarly configures an n+ type gate electrode of a dual gate electrode along with the gate electrode 11 configured from an n+ type semiconductor.

In this way, in the nonvolatile semiconductor memory device of the first embodiment, the first transistor Tr1 acting as a single work function MOSFET shown in FIG. 6 and the second transistor Tr2 acting as a dual work function MOSFET shown in FIG. 7 are mixed on an identical substrate. Therefore, performance of the peripheral circuit can be improved compared to in a semiconductor memory device where only a single work function MOSFET is present.

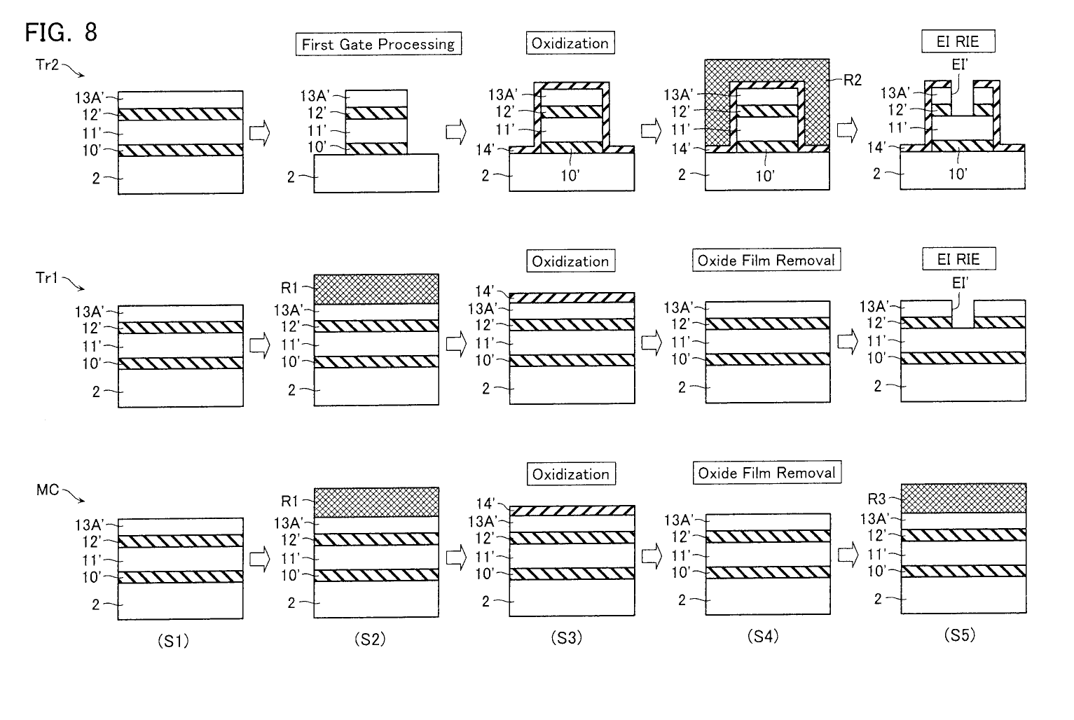

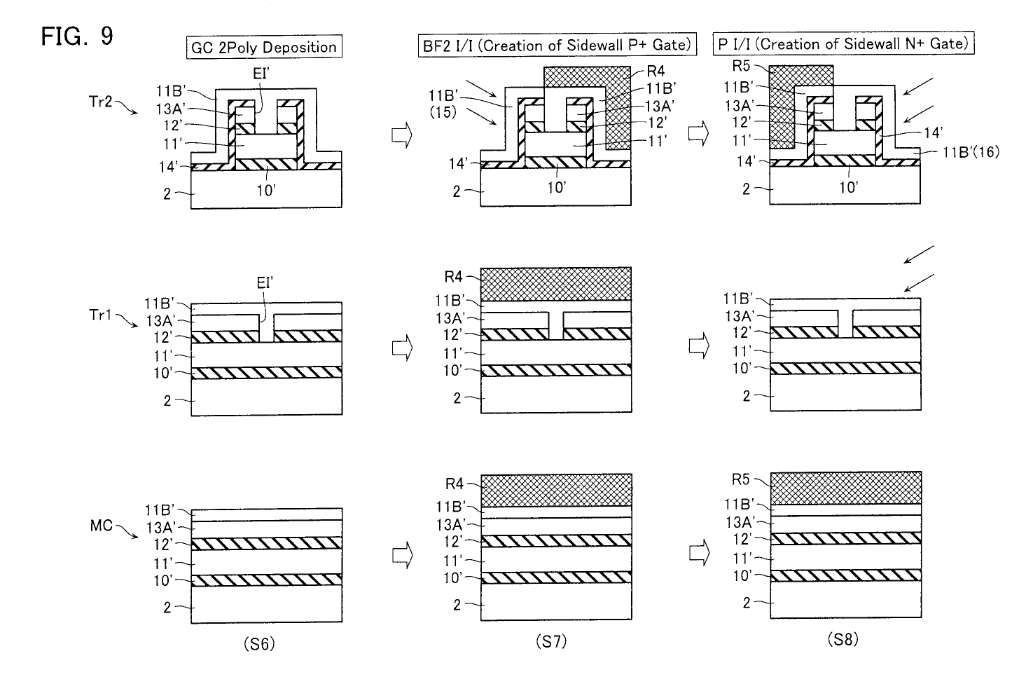

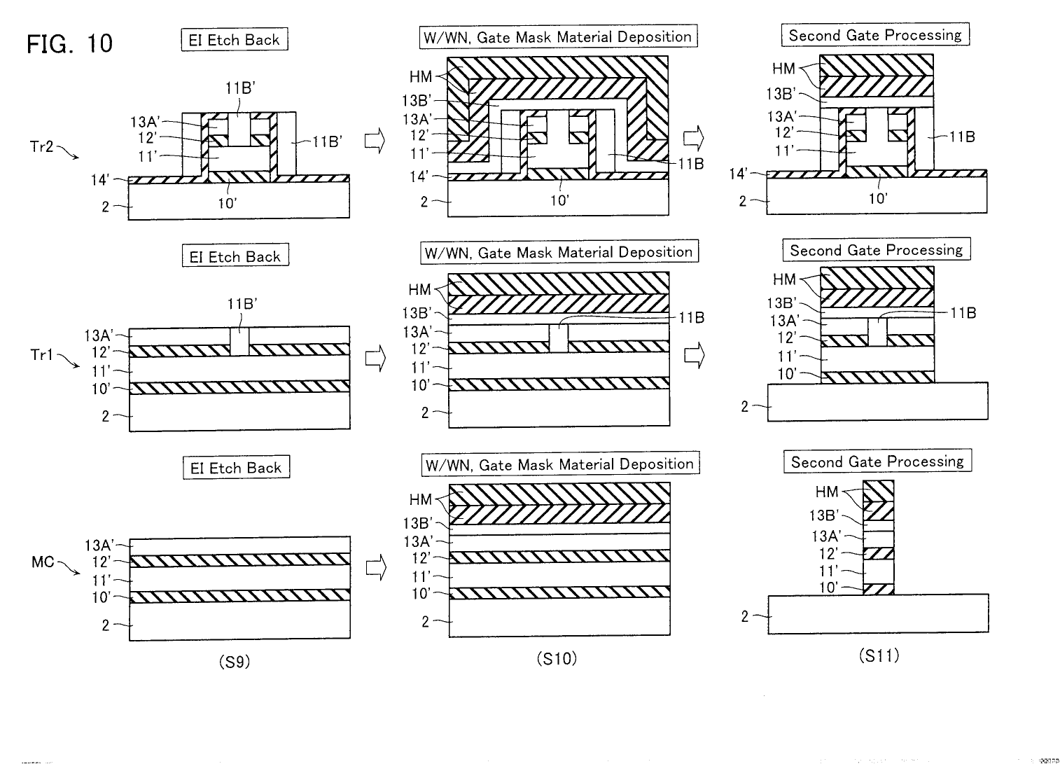

Moreover, in the nonvolatile semiconductor memory device of the first embodiment, by adopting manufacturing steps of the kind that will next be described, the first transistor Tr1 and the second transistor Tr2 of the kinds shown in FIGS. 6 and 7 are enabled to be manufactured by a fewer number of steps. Manufacturing steps of the memory cell MC, the first transistor Tr1, and the second transistor Tr2 of the nonvolatile semiconductor memory device of the first embodiment will be described below with reference to FIGS. 8 to 10. FIGS. 8 to 10 illustrate sequentially in a lateral direction the manufacturing steps of the memory cell MC, the first transistor Tr1, and the second transistor Tr2. The process charts illustrated in one column in a longitudinal direction illustrate steps that are performed at the same time, respectively. For example, the three process charts illustrated on an upper side of a reference sign (S1) illustrate steps that are performed at the same time in the memory cell MC, the first transistor Tr1, and the second transistor Tr2.

First, as shown in FIG. 8, in step S1, a CVD method or the like is employed to deposit, sequentially, on the p type well 2 of a memory cell array region where the memory cell array 111 is formed and on the p type well 2 of a peripheral circuit region where the peripheral circuit is formed, a silicon oxide film 10′, a polysilicon film 11′, a silicon oxide film 12′, and a polysilicon film 13A′. The silicon oxide film 10′, the polysilicon film 11′, the silicon oxide film 12′, and the polysilicon film 13A′ are films that are later to be, respectively, the gate insulating film 10, the floating gate 11, the inter-gate insulating film 12, and the first control gate layer 13A.

Next, in step S2, the memory cell array region and a region where the first transistor Tr1 is formed are protected by a resist R1, and then the silicon oxide film 10′, the polysilicon film 11′, the silicon oxide film 12′, and the polysilicon film 13A′ of a region where the second transistor Tr2 is formed are processed into a shape of the gate electrode of the second transistor Tr2. This processing may also be performed by photolithography and etching adopting the resist R1 as a mask, but a mask other than the resist R1 may also be employed.

In following step S3, WVG (Water Vapor Generation) is employed to deposit a silicon oxide film 14′ on the entirety of the memory cell array region and the peripheral circuit region. This silicon oxide film 14′ is a film that is to be the previously described gate insulating film 14. Note that the silicon oxide film 14′ is formed also on a side surface of a gate electrode structure in the second transistor Tr2.

Next, in step S4, only the region where the second transistor Tr2 is formed is protected by a resist R2, and then the silicon oxide film 14′ is removed in the memory cell array region and the region where the first transistor Tr1 is formed.

Subsequently, in step S5, the resist R2 is removed and a resist R3 is deposited, and then a through-hole EI′ that penetrates the silicon oxide film 14′, the polysilicon film 13A′, and the silicon oxide film 12′ of the first transistor Tr1 and the second transistor Tr2 is formed adopting this resist R3 as a mask. This through-hole EI′ corresponds to the through-hole EI of FIGS. 6 and 7.

Following this, in step S6, the resist R3 is removed, and then an amorphous silicon film 11B′ is deposited on the entire surface of the memory cell array region and the peripheral circuit region. In the first transistor Tr1 and the second transistor Tr2, inside of the through-hole EI′ is also filled by this amorphous silicon film 11B′. This amorphous silicon film 11B′ is formed as the previously described connecting layer 11B in the inside of the through-hole EI.

Next, in step S7, the entire surface of the memory cell array region and the peripheral circuit region excluding a left side surface of the second transistor Tr2 is covered by a resist R4. Then, in order to implant boron ions to the left side surface of the second transistor Tr2, ion implantation of boron fluoride ions (BF2) is performed on the amorphous silicon film 11B′ from an oblique direction. As a result, the amorphous silicon film 11B′ formed on the left side surface of the second transistor Tr2 becomes a p+ type semiconductor and is later to be the previously described p+ type gate electrode 15.

Next, in step S8, the resist R4 is removed and instead a resist R5 is deposited. The resist R5 is deposited so as to cover the entire surface of the memory cell array region and the left side surface of the second transistor Tr2. Then, ion implantation of phosphorus (P) is performed on a surface exposed from the resist R5. As a result, the amorphous silicon film 11B′ changes to an n+ type semiconductor and is to be the previously described connecting layer 11B and n+ type gate electrode 16.

Next, in step S9, the resist R5 is removed, and then dry etching is executed to etch back the amorphous silicon film 11B′ above the silicon oxide film 14′.

In following step S10, a metallic layer 13B′ configured from a metallic film of the likes of tungsten (W) and tungsten nitride (WN) or from a stacked film of a plurality of metallic films is deposited on the entirety of the memory cell array region and the peripheral circuit region, and a silicon nitride film and a TEOS film that function as a hard mask HM are further deposited above the metallic film 13B′.

Next, in step S11, the gate electrodes of the memory cell MC and the first transistor Tr1 are processed adopting this hard mask HM as a mask. Then, ion implantation is performed in a self-aligning manner on these gate electrodes to form the source/drain diffusion layers 3 of the memory cell MC, the first transistor Tr1, and the second transistor Tr2. The above results in completion of structures of the memory cell MC, the first transistor Tr1, and the second transistor Tr2. The second transistor Tr2 is formed as a so-called multi-gate insulating film/dual work function MOSFET.

Note that in FIGS. 6 and 7, n type MOSFETs were shown as examples of the single work function MOSFET and the multi-gate insulating film/dual work function MOSFET, but these MOSFETs may also be configured as p type MOSFETs. In this case, conductivity types of semiconductors are all opposite conductivity types to those shown in FIGS. 6 and 7.

As described above, the manufacturing method of the present embodiment makes it possible to manufacture a semiconductor memory device having a single work function MOSFET and a dual work function MOSFET mixed on one semiconductor substrate, by a small number of steps.

### Second Embodiment

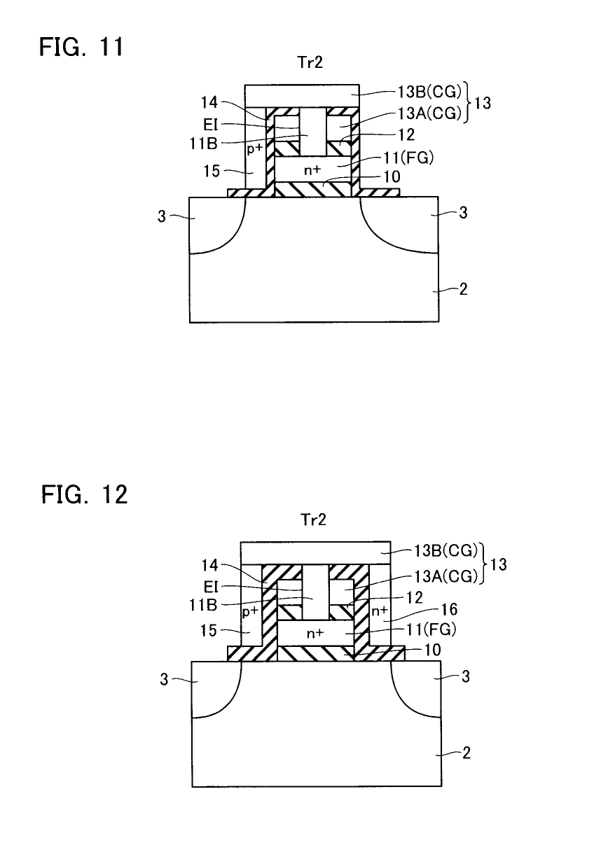

Next, a nonvolatile semiconductor memory device according to a second embodiment will be described with reference to FIG. 11. The nonvolatile semiconductor memory device of the second embodiment has a structure of the second transistor Tr2 that differs from that in the first embodiment and is identical to the first embodiment regarding other portions including overall configuration.

The second transistor Tr2 of this second embodiment is different from the second transistor Tr2 of the first embodiment in that the n+ type gate electrode 16 on the right side of the n+ type gate electrode 11 is omitted. In this second embodiment, the multi-gate insulating film/dual work function MOSFET is formed by the n+ type gate electrode 11 and the p+ type gate electrode 15.

### Third Embodiment

Next, a nonvolatile semiconductor memory device according to a third embodiment will be described with reference to FIG. 12. The nonvolatile semiconductor memory device of the third embodiment has a structure of the second transistor Tr2 that is different from those in the previously described embodiments and is identical to the previously described embodiments regarding other portions including overall configuration.

The second transistor Tr2 of this third embodiment has the gate insulating film 14 having an identical film thickness to that of the gate insulating film 10. In this case, the second transistor Tr2 functions as a single gate insulating film/dual work function MOSFET, and not as a multi-gate insulating film/dual work function MOSFET. By making the film thickness of the gate insulating film 10 identical to the film thickness of the gate insulating film 14, reliability of the gate insulating film of the MOSFET can be increased.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory cell array including a memory transistor; and
a peripheral circuit including a peripheral transistor,
the peripheral transistor including at least a first peripheral transistor and a second peripheral transistor,
the first peripheral transistor and the second peripheral transistor each comprising:
a first gate electrode formed on a gate insulating film;
an inter-gate insulating film formed on a surface of the first gate electrode;
a through-hole formed in the inter-gate insulating film;
a connecting layer formed in the through-hole; and
a second gate electrode formed on a surface of the inter-gate insulating film and connected to the first gate electrode via the connecting layer,
the first gate electrode of the first peripheral transistor being configured by only a semiconductor layer of a first conductivity type, and
the first gate electrode of the second peripheral transistor comprising a first semiconductor layer of the first conductivity type and a second semiconductor layer of a second conductivity type aligned with the first semiconductor layer of the first conductivity type along a gate length direction.

2. The semiconductor memory device according to claim 1, wherein
the gate insulating film of the second peripheral transistor comprises a first gate insulating film and a second gate insulating film,
the first semiconductor layer is formed on the first gate insulating film, and
the second semiconductor layer is formed on the second gate insulating film.

3. The semiconductor memory device according to claim 2, wherein
the second gate insulating film has a film thickness which is smaller compared to that of the first gate insulating film.

4. The semiconductor memory device according to claim 2, wherein
the second gate insulating film is formed also on side surfaces of the first gate electrode and the second gate electrode.

5. The semiconductor memory device according to claim 2, wherein
the second gate insulating film has a film thickness which is identical to that of the first gate insulating film.

6. The semiconductor memory device according to claim 1, wherein
the second gate electrode of the second peripheral transistor comprises a third semiconductor layer positioned on the inter-gate insulating film and a fourth semiconductor layer formed above the third semiconductor layer and connected to the third semiconductor layer via the connecting layer.

7. The semiconductor memory device according to claim 6, wherein
the second gate insulating film is formed also on side surfaces of the first semiconductor layer and the third semiconductor layer.

8. The semiconductor memory device according to claim 7, wherein
the second gate insulating film is formed also between the third semiconductor layer and the fourth semiconductor layer.

9. The semiconductor memory device according to claim 1, wherein
the first gate electrode of the second peripheral transistor further comprises a fifth semiconductor layer of the first conductivity type provided on an opposite side to the second semiconductor layer in relation to the first semiconductor layer.

10. The semiconductor memory device according to claim 9, wherein
the gate insulating film of the second peripheral transistor comprises a first gate insulating film and a second gate insulating film,
the first semiconductor layer is formed on the first gate insulating film, and
the second semiconductor layer is formed on the second gate insulating film.

11. The semiconductor memory device according to claim 10, wherein
the second gate insulating film has a film thickness which is smaller compared to that of the first gate insulating film.

12. The semiconductor memory device according to claim 11, wherein
the second gate insulating film is formed also on side surfaces of the first gate electrode and the second gate electrode.

13. The semiconductor memory device according to claim 10, wherein
the second gate insulating film has a film thickness which is identical to that of the first gate insulating film.

14. A manufacturing method of a semiconductor memory device, the semiconductor memory device comprising a memory cell array region having formed therein a memory cell array including a memory transistor, and a peripheral circuit region having formed therein a peripheral circuit of the memory cell array, the method comprising:
in the memory cell array region and the peripheral circuit region, stacking sequentially on a semiconductor layer a first gate insulating film, a first gate electrode layer, an inter-gate insulating film, and a second gate electrode layer;
in the peripheral circuit region, processing into a shape of a gate electrode the first gate insulating film, the first gate electrode layer, the inter-gate insulating film, and the second gate electrode layer;
in the peripheral circuit region, forming a second gate insulating film adjacent to the first gate insulating film;
in the peripheral circuit region, forming a through-hole that penetrates the second gate electrode layer and the inter-gate insulating film;
in the peripheral circuit region, forming a third gate electrode layer in a periphery of the gate electrode including inside of the through-hole;
in the peripheral circuit region, performing ion implantation of an impurity of a first conductivity type toward the third gate electrode layer formed on a first side of the gate electrode;
in the peripheral circuit region, performing ion implantation of an impurity of a second conductivity type toward the third gate electrode layer formed on a second side on an opposite side to the first side, of the gate electrode; and
in the memory cell array region and the peripheral circuit region, depositing a fourth gate electrode layer above the second gate electrode layer.

15. The manufacturing method of a semiconductor memory device according to claim 14, wherein
the second gate insulating film has a film thickness which is smaller compared to that of the first gate insulating film.

16. The manufacturing method of a semiconductor memory device according to claim 14, wherein
the second gate insulating film has a film thickness which is identical to that of the first gate insulating film.
